(19) United States
(12) Patent Application Publication
(10) Pub. No.: US 2025/0370283 A1
(43) Pub. Date: Dec. 4, 2025

(54) OPTOMECHANICAL DEVICE

(71) Applicant: Commissariat à l'Énergie Atomique et aux Énergies Alternatives, Paris (FR)

(72) Inventor: Guillaume Jourdan, Grenoble (FR)

(73) Assignee: Commissariat à l'Énergie Atomique et aux Énergies Alternatives, Paris (FR)

(21) Appl. No.: 19/224,983

(22) Filed: Jun. 2, 2025

(30) Foreign Application Priority Data
Jun. 4, 2024 (FR) FR2405821

(51) Int. Cl. G02F 1/01; B81B 3/00

(52) U.S. Cl. CPC G02F 1/0128; B81B 3/0083; B81B 2201/0271; G02F 2203/15

(57) ABSTRACT

An optomechanical device. A first element and a second element of the device are mechanically movable with respect to each other. A waveguide of the device includes a portion attached to one of the first and second elements, and an optomechanical resonator of the device is attached to the other of the first and second elements. An actuator of the device is configured to modify a relative position of the first and second elements with respect to each other between a first position where the resonator is optically coupled to the portion of the waveguide and a second position where the resonator is optically decoupled from the portion of the waveguide.

### CROSS REFERENCE TO RELATED APPLICATIONS

This application claims priority to French application number FR2405821, filed Jun. 4, 2024. The contents of this application is incorporated by reference in its entirety.

### TECHNICAL FIELD

The present disclosure generally concerns integrated optomechanical devices, and more particularly integrated optomechanical devices comprising a waveguide and an optical or optomechanical resonator cooperating with the waveguide to receive light.

### PRIOR ART

FIG. 1 shows, in a simplified top view, an example of a device 1 comprising a waveguide 100 and an optical or optomechanical resonator 102.

In the example of FIG. 1, resonator 102 is a disk, for example defined in a layer, for example semiconductor.

When resonator 102 only has an optical function, resonator 102 is called optical resonator 102. When resonator 102 has an optical and mechanical function, resonator 102 is called optomechanical resonator.

Waveguide 100 is for example defined in the same layer as resonator 102.

Waveguide 100 comprises a portion 100A which is arranged at a non-zero distance dc from the resonator.

In the example of FIG. 1, distance de is such that waveguide 100, and more particularly its portion 100A, and resonator 102 are optically coupled to each other. The expression “optically coupled” means, for example, that when light flows through waveguide 100, part of this light can be injected into resonator 102.

For example, when a light signal is injected into waveguide 100 on one side of portion 100A (to the left in FIG. 1) with a power Pin for a wavelength λin, the power Pout of the light signal in waveguide 100 on the other side of portion 100A (to the right in FIG. 1), at this wavelength λin, depends on the resonance wavelength λR of the resonator.

FIG. 2 shows in a curve 200 the variation of power ratio Pout/Pin as a function of the wavelength λin in the device 1 of FIG. 1.

As can be seen in this drawing, when wavelength λin is equal to the wavelength λR of the optical or optomechanical resonator, power Pout then is at a minimum value, which may be zero. However, as wavelength λin becomes distant from wavelength λR, power Pout increases, up to a maximum value.

The principle described hereabove is used in many applications.

For example, resonator 102 may be configured to receive particles and the light signal injected into waveguide 100 is, for example, at a wavelength λin equal to the wavelength λR of the resonator in the absence of particles. The mechanical system, that is, resonator 102, is enabled in the vicinity of its mechanical resonance frequency. The output power Pout varies with the movement of resonator 102 and is thus the image of the movement of the resonator. When a particle reaches resonator 102, the mass of the particle modifies the mass of resonator 102, and thus its mechanical resonance frequency. This change in the mechanical resonance frequency of resonator 102 can be seen in the variation of power Pout, which is the image of the movement of the resonator. The observation of the variation of power Pout with respect to the mechanical activation of resonator 102 enables to detect variations of the mechanical resonance frequency of resonator 102, and thus the presence or the absence of a particle on resonator 102.

For example, resonator 102 may be configured to deform under the effect of an acceleration, and the light signal injected into waveguide 100 is, for example, at a wavelength Ain equal to the wavelength λR of the resonator in the absence of an acceleration. When resonator 102 deforms under the effect of an acceleration, this modifies the optical coupling rate between resonator 102 and portion 100A of waveguide 100. The observation of the change in power Pout then enables to detect, or even to measure, an acceleration to which resonator 102 is subjected. In this case, resonator 102 is an optomechanical resonator.

For example, in applications, it is provided for a plurality of optomechanical resonators 102, for example of the type described in the two above examples, to be optically coupled to a single waveguide 100.

For example, in other applications, it is provided for a plurality of resonators 102, for example of the type described in the two above examples, to be organized in an array comprising rows and columns of resonators 102, and, in each row of resonators 102, for the resonators in the row to all be optically coupled to a single waveguide 100.

As another example, a device 1 may comprise another waveguide having a portion optically coupled to resonator 102, for example on a side of the resonator opposite to the side where the portion 100A of waveguide 100 is coupled to resonator 102. In this case, when a light signal having a wavelength 2 in equal to wavelength λR is injected into waveguide 100, this light signal is transmitted, via resonator 102, to the other waveguide. In this case, resonator 102 is, for example, an optical resonator comprising no mechanical function.

In the above examples, and more generally in a device 1, it may be desirable to disable the optical coupling between resonator 102 and portion 100A of the waveguide. In other words, it may be desirable to prevent light from being transmitted to resonator 102, for example to prevent light at wavelength λin equal to the resonance wavelength λR of resonator 102 at rest from being transmitted to resonator 102.

To disable the optical coupling between resonator 102 and waveguide 100, it has been provided to controllably modify the optical index of resonator 102, so as to control the resonance wavelength of resonator 102 to a value at which the light propagating in waveguide 100 cannot be transmitted to resonator 102, even when the resonance wavelength of the resonator is modified by an environmental factor which is desired to be detected, such as for example an acceleration, a particle, a composition of the medium surrounding resonator 102, etc.

To control the resonance wavelength λR of resonator 102, it is known to control the resonator temperature with a heating element to take advantage of the temperature dependence of the value of wavelength λR.

However, known solutions for selectively enabling and disabling the optical coupling between a waveguide 100 and a resonator 102 of a device 1 have disadvantages. For example, known solutions which rely on a control of the temperature of resonator 102 are complex and cumbersome to implement, and further exhibit inertia. Further, these solutions are energy-intensive due to the thermal power required to implement a heating.

### SUMMARY OF THE INVENTION

There exists a need for a device in which the optical coupling between a waveguide and an optical or optomechanical resonator can be selectively enabled and disabled, which overcomes all or part of the disadvantages of known devices in which the optical coupling between a waveguide and an optical or optomechanical resonator can be selectively enabled and disabled.

An embodiment provides an optomechanical device comprising:
a first element and a second element mechanically movable with respect to each other;
a waveguide comprising a portion attached to one of the first and second elements;
an optomechanical device attached to the other of the first and second elements; and
an actuator configured to modify a relative position of the first and second elements with respect to each other between a first position where the resonator is optically coupled to said portion of the waveguide and a second position where the resonator is optically decoupled from said portion of the waveguide.

According to an embodiment:
the device comprises a substrate and a first layer resting on the substrate;
the first layer comprises a first portion suspended above the substrate and movable with respect to the substrate; and
the first element of the device comprises the first portion of the first layer.

According to an embodiment, the first layer extends in thickness in a direction orthogonal to a main surface of the substrate and the first portion of the first layer is movable with respect to the substrate in a plane parallel to the main surface of the substrate.

According to an embodiment:
the first layer comprises a second portion which is fixed with respect to the substrate;
the first and second portions of the first layer are mechanically coupled to each other by at least one link allowing a relative movement of the first and second portions of the first layer with respect to each other; and
the second element of the device comprises the substrate or the second portion of the first layer.

According to an embodiment, said at least one link comprises a single pivot link and the second element of the device comprises the substrate.

According to an embodiment:
the first layer comprises a second portion suspended above the substrate and movable with respect to the substrate;
the first and second portions of the first layer are mechanically coupled to each other by at least one link allowing a relative movement of the first and second portions with respect to each other;
the second portion of the first layer and the substrate are mechanically coupled to each other by at least one link allowing a relative movement of the second portion of the first layer and of the substrate with respect to each other; and
the second element of the device comprises the second portion of the first layer.

According to an embodiment, the device comprises a second layer resting on the substrate, between the substrate and the first layer, the resonator and waveguide being defined in the second layer.

According to an embodiment, the device comprises at least a third layer between the substrate and the second layer and at least a fourth layer between the second layer and the first layer.

According to an embodiment, the portion of the waveguide or the resonator which is attached to the first portion is attached to this first portion by at least one anchor pad defined in said at least one fourth layer.

According to an embodiment, said at least one link are at least partly defined in the first layer.

According to an embodiment, the actuator comprises at least one electrostatic actuator comprising a capacitive element having a first electrode at least partly defined in the first element.

According to an embodiment, the device comprises at least one stop determining a non-zero minimum gap between the portion of the waveguide and the resonator in the first position.

According to an embodiment, the device comprises an additional optical or optomechanical resonator attached to said other of the first and second elements so that:
the additional resonator is optically decoupled from said portion of the waveguide in the first position and is optically coupled to said portion of the waveguide in the second position; or the additional resonator is optically coupled to said portion of the waveguide in the first position and is optically decoupled from said portion of the waveguide in the second position; or
the additional resonator is optically coupled to a portion of an additional waveguide of the device in the first position and is optically decoupled from said portion of the additional waveguide in the second position, said portion of the additional waveguide being attached to one of the first and second elements.

According to an embodiment, the device comprises an additional waveguide having a portion attached to said one of the first and second elements so that:

the resonator is optically decoupled from said portion of the additional waveguide in the first position and is optically coupled to said portion of the additional waveguide in the second position; or
the resonator is optically coupled to said portion of the additional waveguide in the first position and is optically decoupled from said portion of the additional waveguide in the second position.

According to an embodiment, the device comprises an additional waveguide having a portion attached to said other one of the first and second elements so that said portion of the additional waveguide is optically coupled to the resonator.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1, previously described, shows, in a simplified top view, an example of an optical or optomechanical device;

FIG. 2, previously described, illustrates in a curve an optical response of the device of FIG. 1;

FIG. 3 shows, in a simplified top view, an example of an embodiment of an optomechanical device;

FIG. 4 is a simplified cross-section along a plane AA of FIG. 3;

FIG. 5 is a simplified cross-section view along a plane BB of FIG. 3;

FIG. 6 shows, in a simplified top view, an example of an alternative embodiment of the optomechanical device of FIGS. 3 to 5;

FIG. 7 is a simplified cross-section view along a plane AA of FIG. 6;

FIG. 8 shows, in a simplified top view, an example of still another alternative embodiment of the optomechanical device of FIGS. 3 to 5;

FIG. 9 shows, in a simplified top view, an example of still another alternative embodiment of the optomechanical device of FIGS. 3 to 5;

FIG. 10 is a simplified cross-section view along a plane AA of FIG. 9;

FIG. 11 shows, in a simplified top view, an example of another embodiment of an optomechanical device;

FIG. 12 shows, in a simplified top view, an example of still another embodiment of an optomechanical device;

FIG. 13 shows, in a simplified top view, an example of still another embodiment of an optomechanical device;

FIG. 14 shows, in a simplified top view, an example of still another embodiment of an optomechanical device;

FIG. 15 shows, in a simplified top view, an example of still another embodiment of an optomechanical device;

FIG. 16 shows, in a simplified top view, an example of still another embodiment of an optomechanical device;

FIG. 17 shows, in a simplified top view, another example of embodiment of the device of FIGS. 3 to 5;

FIG. 18 shows, in a simplified top view, still another example of embodiment of the device of FIGS. 3 to 5;

FIG. 19 shows, in a simplified top view, an example of still another alternative embodiment of the optomechanical device of FIGS. 3 to 5;

FIG. 20 shows, in a simplified top view, an example of another embodiment of an optoelectronic device.

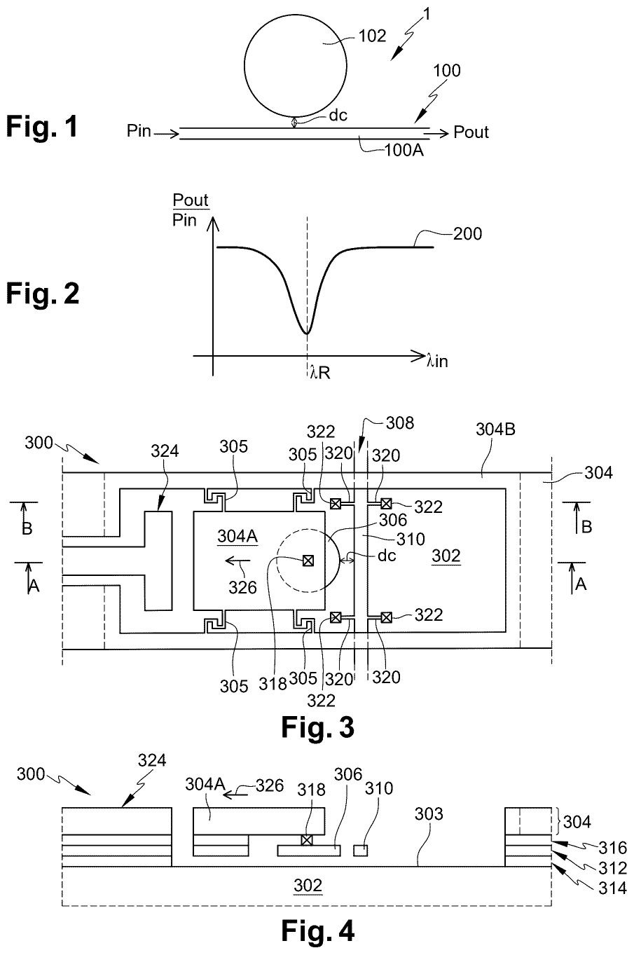

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the methods of manufacturing the integrated optical devices described herein have not been detailed, the manufacturing of the embodiments and variants of these devices based on usual steps of manufacturing of known integrated optical devices being within the abilities of those skilled in the art based on the following description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

Unless indicated otherwise, when reference is made to two elements attached to each other, this means that these two elements are mechanically integral with each other, or in other words, that a displacement applied to a first one of the two elements is then also applied to the second one of the two elements. Still in other words, this means that the relative position of these two elements with respect to each other is fixed (or constant).

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

To selectively enable and disable the coupling between a portion of a waveguide and an optical or optomechanical resonator, there is here provided an integrated device comprising an optical or optomechanical resonator and a waveguide, in which a value of an optical coupling distance between the resonator and a portion of the waveguide is controllable between at least two values. For a first one of the two values, light can be transmitted between the waveguide portion and the resonator, for example when this light is at the resonance wavelength of the resonator, and, for a second one of the two values, light cannot be transmitted between the waveguide portion and the resonator, for example even when this light is at the resonance wavelength of the resonator. In other words, the optical coupling between the waveguide and the resonator is enabled when the coupling distance between the resonator and the waveguide portion is at its first value, and is disabled when the coupling distance between the resonator and the waveguide portion is at its second value.

To achieve this, the integrated device comprises two elements movable with respect to each other. The waveguide portion is attached to one of the two elements and the resonator is attached to the other of the two elements. The device further comprises an actuator configured to modify the position of the two elements with respect to each other between at least a first position in which the waveguide and the resonator are optically coupled and a second position in which the waveguide and resonator are optically decoupled. In other words, the optical coupling between the resonator and the waveguide, and more specifically the waveguide portion, is enabled in the first position and disabled in the second position.

In the provided device, as will be described in more detail in relation with the examples of FIGS. 3 to 20, a layer rests on a surface of a substrate and one of the two movable elements comprises, or corresponds to, a portion of this layer, this portion being suspended above the substrate and movable with respect to the substrate. As an example, the second one of the two movable elements comprises the substrate, for example corresponds to the substrate. As an alternative example, the second one of the two movable elements comprises another portion of the layer resting on the substrate, this other portion being fixed with respect to the substrate and being at least partly suspendable above it, or, alternatively being movable with respect to the substrate and suspended above the substrate.

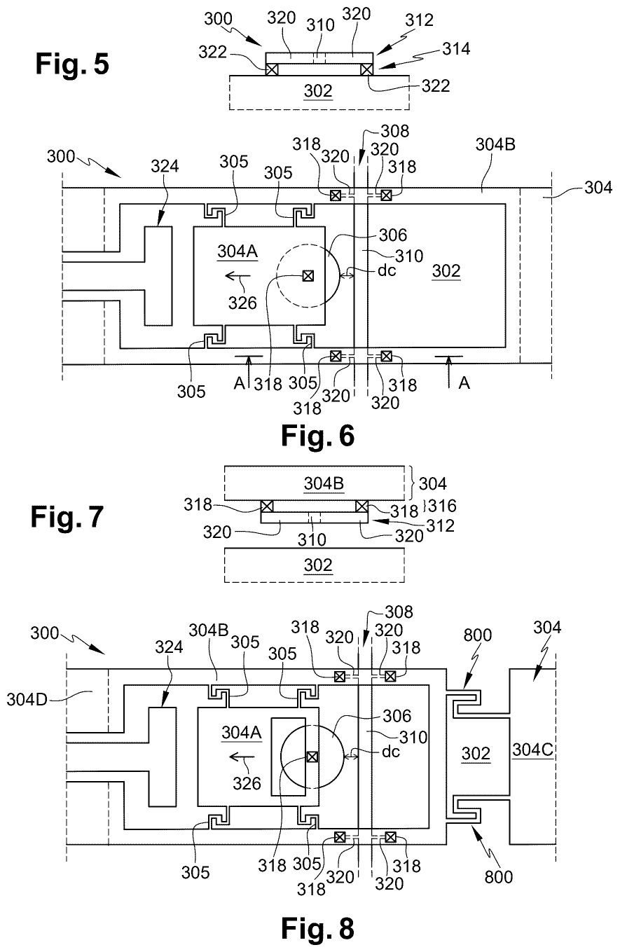

FIGS. 3 to 5 illustrate an example of an embodiment of such a device 300, FIG. 3 being a simplified top view of device 300, FIG. 4 being a simplified cross-section view along a plane AA of FIG. 3, and FIG. 5 being a simplified cross-section view along a plane BB of FIG. 3.

Device 300 comprises a substrate 302, for example a semiconductor substrate, for example made of silicon.

Device 300 comprises a layer 304 resting on substrate 302, that is, on a main surface 303 of substrate 302 (the upper surface of the substrate in FIGS. 4 and 5). Layer 304 does not rest directly on substrate 302, that is, it is not in contact with substrate 302. The thickness of layer 304 is measured in a direction orthogonal to surface 303 of substrate 302. Layer 304 is for example a semiconductor layer, for example made of silicon, of germanium, or of silicon-germanium.

Layer 304 comprises a portion 304A which is suspended above substrate 302, that is, above surface 303. In other words, there is an empty space between portion 304A of layer 304 and substrate 302. Portion 304A of layer 304 is movable with respect to the substrate, in this example in a plane parallel to surface 303 of substrate 302.

For example, the movable portion 304A of layer 304 is mechanically coupled to a portion 304B of layer 304 by links 305.

In the example of FIGS. 3 to 5, portion 304B has, for example, a general rectangular frame shape (delimited by dotted lines in FIG. 3).

In the example of FIGS. 3 to 5, portion 304B is, for example, also at least partly suspended above substrate 302. For example, both long sides of frame 304B are suspended above substrate 302.

In the embodiment of FIGS. 3 to 5, unlike portion 304A, portion 304B is fixed with respect to substrate 302. For example, parts of portion 304B, for example the short sides of frame 304B, are attached to substrate 302. For example, the parts of portion 304B which are attached to substrate 302 rest on top of and in contact with an upper surface of a stack of layers in contact two by two, the lower surface of the stack of layers resting on top of and in contact with surface 303 of substrate 302.

Links 305 are configured to allow a displacement of portion 304A with respect to portion 304B. In this respect, links 305 are said to be flexible. For example, the dimensions of links 305 are determined so as to allow a deformation of links 305 allowing the relative movement of portions 304A and 304B with respect to each other. Links 305 are, for example, at least partly defined in layer 304.

Device 300 comprises a first element and a second element movable with respect to each other.

In this embodiment, the first element comprises portion 304A of layer 304, and the second element comprises, for example is formed by, substrate 302. Thus, as portion 304A moves with respect to substrate 302, the first element moves correspondingly with respect to the second element.

Device 300 comprises an optical or optomechanical resonator 306 and a waveguide 308 comprising a portion 310.

In this embodiment, resonator 306 is attached to portion 304A of layer 304 and portion 310 of waveguide 308 is attached to substrate 302, for example to surface 303 of substrate 302. In other words, resonator 306 is attached to the first one of the two elements movable with respect to each other, and portion 310 of waveguide 308 is attached to the second one of the two elements movable with respect to each other.

Waveguide 308 and resonator 306 are defined in a same layer 312.

Layer 312 preferably has a smaller thickness than layer 304. Layer 312 is, for example, called NEMS (Nano Electro-Mechanical System) layer, while layer 304 is, for example, called MEMS (Micro Electro-Mechanical System) layer. Layer 312 is, for example, a semiconductor layer, for example made of silicon, of germanium, or of silicon-germanium. As an alternative example, layer 312 may be made of a dielectric material, for example of silicon nitride. For example, the material of layer 312 is adapted to guiding an optical signal at an operating wavelength of device 300.

In this example, layer 312 is arranged between layer 304 and substrate 302. Thus, in this example, waveguide 308 and resonator 306 are arranged between layer 304 and substrate 302, without being in direct contact with layer 304 and substrate 302. More particularly, layer 312 rests on top of and in contact with at least one layer 314 resting on top of and in contact with substrate 302, and, further, layer 304 rests on top of and in contact with at least one layer 316 resting on top of and in contact with layer 312. As an example, layers 316 and 304 are made of different materials, for example selectively etchable with respect to each other. As an alternative example, layers 316 and 304 are made of the same material, and may, for example, be formed one after the other during a same deposition step by providing a mask resting on layer 312 at the locations where layer 316 is not to be present.

In this embodiment where resonator 306 is attached to portion 304A of layer 304, resonator 306 is attached to portion 304A by at least one anchor pad 318. As an example, each anchor pad 318 of an element, such as resonator 306, defined in layer 312 and attached to layer 304, is defined in layer 316. In this example, resonator 306 is thus suspended under layer 304, and suspended above substrate 302.

In this example where resonator 306 is a disk, a single anchor pad 318 arranged at the center of disk 306 attaches disk 306 to portion 304A of layer 304. In other, non-illustrated examples, resonator 306 is formed by a ring, for example circular or in the shape of a racetrack. In these other examples, holding arms defined in layer 312 extend from the resonator to one or more anchor pads 318, preferably arranged inside the ring. In still other examples, resonator 306 is a photonic crystal resonator, attached to portion 304A of layer 304 by at least one anchor pad 318, and, if required, by at least one holding arm.

In this embodiment where portion 310 of waveguide 308 is attached to substrate 302, this portion 310 is attached to the substrate by holding arms 320 and by anchor pads 322. As an example, each anchor pad 322 of an element, such as portion 310 of waveguide 308, defined in layer 312 and attached to substrate 302, is defined in layer 314. As an example, each holding arm 320 is defined in layer 312, and extends from portion 310 to a corresponding anchor pad 322. In FIG. 5, the boundary between portion 310 of waveguide 308 and holding arms 320 is shown by dotted lines. In this example, portion 310 of waveguide 308 is thus suspended above substrate 302, and suspended below layer 304.

The device comprises an actuator 324. Actuator 324 is configured to modify the relative position of the first and second elements movable with respect to each other, that is, in this embodiment, to modify the relative position of portion 304A of layer 304 with respect to substrate 302. More particularly, actuator 324 is configured to modify the relative position of the first and second elements movable with respect to each other between a first position where resonator 306 and portion 310 of waveguide 308 are optically coupled to each other, and a second position where resonator 306 and portion 310 of waveguide 308 are optically decoupled from each other.

As an example, in the first position, the optical coupling distance de between portion 310 of waveguide 308 and resonator 306 is such that light can be transmitted, via an optical coupling in empty space dc, between portion 310 and resonator 306. As an example, in the second position, the optical coupling distance dc is such that light cannot be transmitted, via an optical coupling in empty space dc, between portion 310 and resonator 306. The value of distance dc is smaller in the first position than in the second position. In other words, in the first position, the optical coupling rate, which is proportional to exp-de/Le with exp the exponential function and Le the characteristic distance of exponential decay of the optical coupling, is sufficiently high for light to be transmitted between portion 310 and resonator 306, whereas in the second position, this optical coupling rate is sufficiently low for light not to be transmitted between portion 310 and resonator 306. As an example, distance Le is related to the characteristic distances of exponential decay of the evanescent fields of the two optical modes that are optically coupled, one of these two modes being in resonator 306, the other of these two modes being in portion 310 of waveguide 308. As an example, the optical coupling rate is sufficiently low for no light to be able to be transmitted between portion 310 and resonator 306 when dc>3.Le. As a more specific example, between the first and second positions, the variation of optical coupling distance de is provided to be greater than 3.Le, for example so as to obtain a decrease in the coupling rate by a value greater than or equal to exp⁻³.

In this example, actuator 324 comprises an electrostatic actuator. The electrostatic actuator comprises a first electrode at least partly defined in the first of the two elements movable with respect to each other. In addition, the electrostatic actuator comprises a second electrode forming a capacitive element with the first electrode. For example, in the absence of a biasing applied between the two electrodes of the capacitive electrostatic actuator, the actuator has no effect on the relative position of the two elements movable with respect to each other, and, in this example, this relative position then corresponds to the first position described hereabove. Conversely, when a non-zero biasing, for example positive, is applied between the two electrodes of the capacitive electrostatic actuator, this tends to bring the two electrodes closer to each other, which modifies the relative position of the two elements movable with respect to each other. In this example, when the two electrodes of the electrostatic actuator move towards each other, this results in that portion 304A moves as illustrated by an arrow 326 in the drawings. In this example, this displacement of portion 304A with respect to substrate 302 draws resonator 306 and portion 310 of waveguide 308 away from each other, or, in other words, increases distance dc. In this example, when a non-zero, for example, positive, biasing is applied between the electrodes of the capacitive electrostatic actuator, the relative position of the first and second elements movable with respect to each other then corresponds to the second above-described position.

FIGS. 6 and 7 illustrate an example of an alternative embodiment of device 300, FIG. 6 being a simplified top view of device 300 similar to the top view of FIG. 3, and FIG. 7 being a simplified cross-section view along a plane AA of FIG. 6.

The device 300 of FIGS. 6 and 7 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIGS. 6 and 7.

In the embodiment of FIGS. 3 to 5, the first one of the two elements movable with respect to each other comprises, or corresponds to, portion 304A and the second one of the elements movable with respect to each other comprises, or corresponds to, substrate 302. In the embodiment of FIGS. 6 and 7, the first one of the two elements movable with respect to each other comprises, or corresponds to, the portion 304A movable with respect to substrate 302, and the second one of the elements movable with respect to each other comprises, or corresponds to, the portion 304B of layer 304 which is fixed with respect to substrate 302.

Thus, in this variant, portion 310 of waveguide 308 is attached to the fixed portion 304B of layer 304 rather than to substrate 302.

For example, portion 310 of waveguide 308 is attached to portion 304B of layer 304 by anchor pads 318 and by holding arms 320, each extending from portion 310 to a corresponding anchor pad 318. In FIG. 7, the boundary between portion 310 and holding arms 320 is shown by dotted lines.

For example, portion 304B has, as in FIGS. 3 to 5, the general shape of a rectangular frame having its long sides suspended above substrate 302, anchor pads 318 attaching the portion 310 of waveguide 308 being in direct contact (mechanically connected) with these long sides.

As compared with the embodiment of FIGS. 3 to 5, in the alternative embodiment of FIGS. 6 and 7, the mechanical loop between resonator 306 and the portion 310 of waveguide 308 is shorter, which enables to limit the amplitude of the relative displacements between these two elements when these relative displacements result from thermal expansion or substrate deformation. By mechanical loop, there is here meant all the elements forming part of the shortest mechanical coupling path between resonator 306 and portion 310 of the waveguide.

For example, in FIGS. 6 and 7, this mechanical loop successively comprises, from resonator 306 to portion 310, anchor pad 318 from resonator 306 to portion 304A of layer 304, portion 304A of layer 304, the flexible links for mechanically coupling the movable portion 304A of layer 304 to the fixed portion 304B of layer 304, the anchor pads 318 of holding arms 320 to portion 304B of layer 304, and holding arms 320 mechanically coupling portion 310 of waveguide 308 to these pads 318 fixed to portion 304B of layer 304.

FIG. 8 shows an example of another alternative embodiment of device 300, FIG. 8 being a simplified top view of device 300 similar to the top views of FIGS. 3 and 6.

The device 300 of FIG. 8 has many similarities and features in common with the device 300 of FIGS. 6 and 7, and only the differences between these two devices 300 are here highlighted. Thus, unless otherwise indicated, everything that has been described for the devices 300 of FIGS. 6 and 7 applies to the device 300 of FIG. 8.

In the alternative embodiment of FIG. 8, layer 304 comprises a portion 304C fixed with respect to substrate 302, this portion 304C resting, for example, on top of and in contact with the stack of layers 316, 312, 314 (see FIG. 4). Further, although portion 304B of layer 304 is considered as fixed with respect to substrate 302, this portion 304B is suspended above substrate 302, and comprises a part, for example a short side (for example, to the right in FIG. 8) of rectangular frame 304B, which is mechanically coupled to the fixed portion 304C by links 800 at least partly defined in layer 304. Links 800 are flexible, that is, these links 800 are capable of deforming so that deformations of substrate 302 with respect to layer 304 and/or vibrations of substrate 302 are at least partly absorbed by links 800 and are not transmitted to portion 304B. In other words, links 800 are configured to decrease the stress exerted by substrate 302 on fixed portion 304B. However, portion 304B keeps a direct mechanical connection with a portion 304D of layer 304 which is fixed with respect to substrate 302, this portion 304D resting, for example, on top of and in contact with the stack of layers 316, 312, 314 (see FIG. 4). For example, the other short side of frame 304B (to the left in FIG. 8) is in direct contact with portion 304D, or even rests on top of and in contact with the stack of layers 316, 312, and 314.

Although in the example of FIG. 8, the second one of the two elements movable with respect to each other comprises portion 304B of layer 304 and portion 310 of waveguide 308 is attached to portion 304B, those skilled in the art will be capable of adapting the embodiment of FIG. 8 to the case where the second one of the two elements movable with respect to each other is, as in the example of FIGS. 3 to 5, substrate 302, the portion 310 of waveguide 308 then being attached to substrate 302.

In the examples of FIGS. 3 to 5 and FIGS. 6 and 7, resonator 306 is largely, for example by more than 70%, arranged under and opposite portion 304A of layer 304. Thus, there is a small surface area, for example smaller than 30%, of resonator 306 that can receive particles when it is desired to use device 300 as a particle detector. In the example of FIG. 8, portion 304A comprises a recess, that is, an opening through layer 304, so as to increase the surface area of resonator 306 that can be reached by particles. Of course, those skilled in the art will be capable of providing such recesses in other examples of the device 300 described herein, for example in the device 300 of FIGS. 3 to 5 or FIGS. 6 and 7, or, conversely, of omitting the recess in the example of device 300 of FIG. 8.

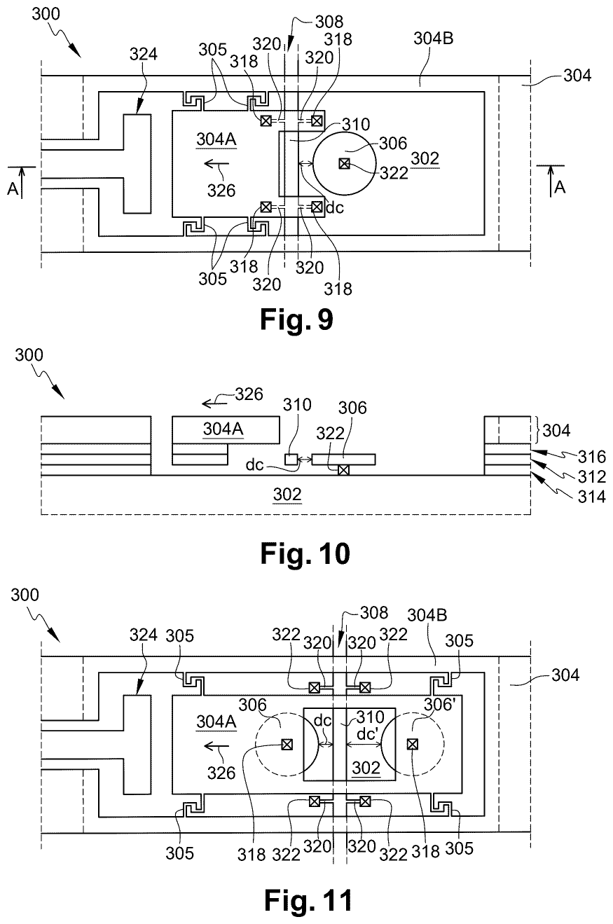

FIGS. 9 and 10 illustrate an example of still another embodiment of device 300, FIG. 9 being a simplified top view of device 300 similar to the top view of FIGS. 3, 6, and 8, and FIG. 10 being a simplified cross-section view along a plane AA of FIG. 9.

The device 300 of FIGS. 9 and 10 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIGS. 9 and 10.

In the embodiment of FIGS. 3 to 5, the first one of the two elements movable with respect to each other comprises portion 304A and the second one of the elements movable with respect to each other comprises, or corresponds to, substrate 302. Further, in the embodiment of FIGS. 3 to 5, resonator 306 is attached to the first element, and, more particularly, to portion 304A, and portion 310 of waveguide 308 is attached to the second element, and, more particularly, to substrate 302.

In the alternative embodiment of FIGS. 9 and 10, the first one of the two elements movable with respect to each other comprises portion 304A movable with respect to substrate 302, and the second one of the elements movable with respect to each other comprises, or corresponds to, substrate 302. However, in this variant, waveguide 308 is attached to the first one of these two elements, and, more particularly, to movable portion 304A, and resonator 306 is attached to the second one of the two elements, and, more particularly, to substrate 302 in this example.

For example, portion 310 of waveguide 308 is attached to portion 304A by holding arms 320 and by anchor pads 318, and resonator 306 is attached to substrate 302 by an anchor pad 322.

Those skilled in the art will be capable of adapting the alternative embodiment of FIGS. 9 and 10 to the alternative embodiment of FIGS. 6 and 7 or FIG. 8 by attaching the resonator to portion 304B of layer 304, for example by providing for resonator 306 to be attached under part of portion 304B forming a beam coupling the two long sides of portion 304B when this portion 304B has the general shape of a rectangular frame.

It should be noted that, although this is not shown in the previously-described FIGS. 3 to 10, preferably waveguide 308 comprises, on either side of portion 310, portions which are attached to the substrate. In this case, when portion 310 of the waveguide is attached to the first one of the two elements movable with respect to each other, and, more particularly, to portion 304A of layer 304, the displacement of portion 304A with respect to substrate 302 causes a deformation of waveguide 308 on either side of portion 310. Advantageously, this is not the case when portion 310 of waveguide 308 is attached to the second one of the two elements movable with respect to each other, and more particularly to a part of this second element which is fixed with respect to substrate 302, as is the case, for example, in the example of FIGS. 3 to 5, of FIGS. 6 and 7, or of FIG. 8.

FIG. 11 shows, in a simplified top view, an example of another embodiment of device 300, FIG. 11 being a simplified top view of device 300 similar to the top views of FIGS. 3, 6, 8, and 9.

The device 300 of FIG. 11 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 11.

In this embodiment, device 300 comprises an additional optical or optomechanical resonator 306′, for example identical to resonator 306. As an example, resonator 306′ is defined in the same layer 312 as resonator 306.

In this embodiment where resonator 306 is attached to the first one of the two elements movable with respect to each other, and more specifically to portion 304A of layer 304, the additional resonator 306′ is also attached to this first element. For example, resonator 306′ is attached to portion 304A by an anchor pad 318. A coupling gap dc′ separates resonator 306′ from portion 310 of waveguide 308.

In this embodiment, portion 310 of waveguide 308 is attached to the second one of the two elements movable with respect to each other, and, more particularly, to substrate 302 in this example. However, in other, non-illustrated examples where the second element comprises, or corresponds to, portion 304B of layer 304, portion 310 of waveguide 308 may be attached to this portion 304B as is the case in FIGS. 6 and 7 and FIG. 8.

In the device 300 of FIG. 11, when the first and second elements movable with respect to each other are in the first position where resonator 306 is optically coupled to portion 310 of waveguide 308, resonator 306′ is then optically decoupled from portion 310 of waveguide 308. Conversely, when the first and second elements movable with respect to each other are in the second position where resonator 306 is optically decoupled from portion 310 of waveguide 308, the resonator 306′ is then optically coupled to portion 310 of waveguide 308.

For example, the relative position of the two resonators 306 and 306′ with respect to each other is fixed (constant), and resonators 306 and 306′ are arranged respectively on either side of portion 310 of waveguide 308, for example, in the direction of relative displacement of the first and second elements with respect to each other.

In the example of FIG. 11, resonator 306, and thus resonator 306′, are attached to the first one of the two elements movable with respect to each other, and portion 310 of waveguide 308 is attached to the second one of the two elements movable with respect to each other. Those skilled in the art will be capable of adapting the embodiment of FIG. 11 to the embodiment described in relation with FIGS. 9 and 10 where portion 310 of waveguide 308 is attached to the first one of the two elements movable with respect to each other, and, more particularly, to portion 304A, and where resonator 306 is attached to the second one of the two elements movable with respect to each other, by attaching the additional resonator 306′ to the second one of the two elements movable with respect to each other, for example to substrate 302 or to portion 304B, regardless of whether the latter is of the type described in relation with FIGS. 6 and 7, or of the type described in relation with FIG. 8.

The device 300 of the type described in relation with FIG. 11 controls which of resonators 306 and 306′ waveguide 308 is coupled to.

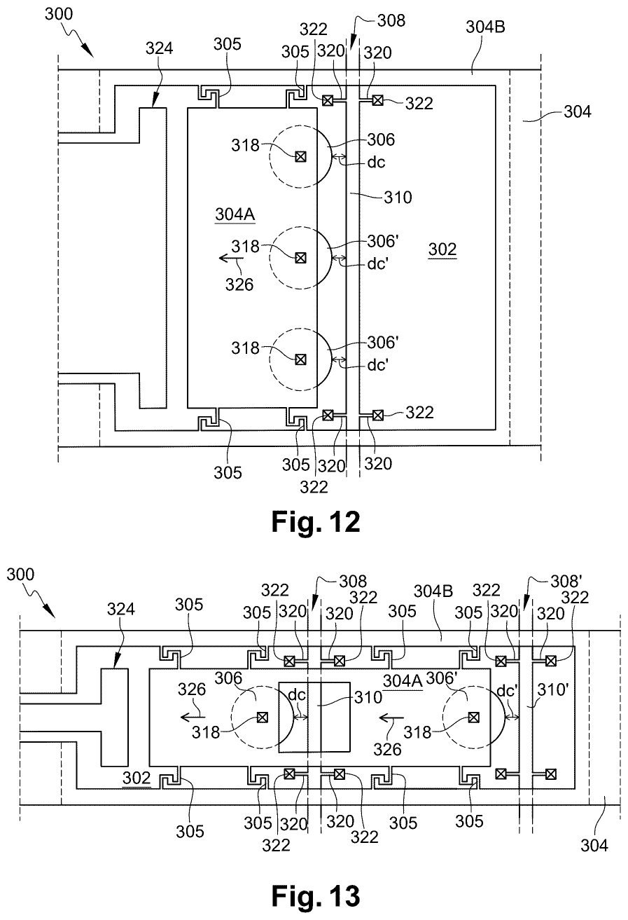

FIG. 12 shows, in a simplified top view, an example of still another embodiment of device 300, FIG. 12 being a simplified top view of device 300 similar to the top views of FIGS. 3, 6, 8, 9, and 11.

The device 300 of FIG. 12 has many similarities and features in common with the device 300 of FIG. 11, and only the differences between these two devices 300 are here highlighted. Thus, unless otherwise indicated, all that has been described for the device 300 of FIG. 11 applies to the device 300 of FIG. 12.

In the device 300 of FIG. 12, when the first and second elements movable with respect to each other are in the first position where resonator 306 is optically coupled to portion 310 of waveguide 308, resonator 306′ is also optically coupled to portion 310 of waveguide 308. Conversely, when the first and second elements movable with respect to each other are in the second position where resonator 306 is optically decoupled from portion 310 of waveguide 308, resonator 306′ is then optically decoupled from portion 310 of waveguide 308. Preferably, the coupling gap dc between resonator 306 and portion 310 and the coupling gap dc′ between resonator 306′ and portion 310 of waveguide 308 have identical values, which vary in the same way during a relative displacement of the first and second elements with respect to each other.

For example, the relative position of the two resonators 306 and 306′ with respect to each other is fixed (constant), and resonators 306 and 306′ are arranged on the same side of portion 310 of waveguide 308, for example, in the direction of relative displacement of the first and second elements with respect to each other.

In the example of FIG. 12, resonator 306, and thus resonator 306′, are attached to the first one of the two elements movable with respect to each other, and portion 310 of waveguide 308 is attached to the second one of the two elements movable with respect to each other. Those skilled in the art will be capable of adapting the embodiment of FIG. 12 to the alternative embodiment described in relation with FIGS. 9 and 10 where portion 310 of waveguide 308 is attached to the first one of the two elements movable with respect to each other, and, more particularly, to portion 304A, and where resonator 306 is attached to the second one of the two elements movable with respect to each other, by attaching the additional resonator 306′ to the second one of the two elements movable with respect to each other, for example to substrate 302 or to portion 304B regardless of whether the latter is of the type described in relation with FIGS. 6 and 7, or of the type described in relation with FIG. 8.

As an example, device 300 may comprise more than one additional resonator 306′, for example two additional resonators as shown in FIG. 12.

The device 300 of the type described in relation with FIG. 12 enables to selectively enable or disable the optical coupling between a plurality of resonators and a single waveguide.

FIG. 13 shows, in a simplified top view, an example of still another embodiment of device 300, FIG. 13 being a simplified top view of device 300 similar to the top views of FIGS. 3, 6, 8, 9, 11, and 12.

The device 300 of FIG. 13 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 13.

In this embodiment, device 300 comprises an additional optical or optomechanical resonator 306′, for example identical to resonator 306. As an example, resonator 306′ is defined in the same layer 312 as resonator 306.

Further, in this embodiment, device 300 comprises an additional waveguide 308′ comprising a portion 310′. As an example, waveguide 308′ is defined in the same layer 312 as waveguide 308.

In this embodiment where resonator 306 is attached to the first one of the two elements movable with respect to each other, and more specifically to portion 304A of layer 304, the additional resonator 306 is also attached to this first element. For example, resonator 306′ is attached to portion 304A by an anchor pad 318. A coupling gap dc′ separates resonator 306′ from portion 310′ of waveguide 308′.

In this embodiment where portion 310 of waveguide 308 is attached to the second one of the two elements movable with respect to each other, portion 310′ of the additional waveguide 308′ is also attached to the second one of the two elements movable with respect to each other. For example, in this example where portion 310 of waveguide 308 is attached to substrate 302, portion 310′ of waveguide 308′ is also attached to substrate 302. However, in other examples, not shown, where the second element comprises portion 304B of layer 304, the portions 310 and 310′ of the respective waveguides 308 and 308′ may be attached to this portion 304B, as is the case for portion 310 in FIGS. 6 and 7 and in FIG. 8.

In the device 300 of FIG. 13, when the first and second elements movable with respect to each other are in the first position where resonator 306 is optically coupled to the portion 310 of waveguide 308, resonator 306′ is then optically coupled to portion 310′ of waveguide 308′. Conversely, when the first and second elements movable relative to each other are in the second position where resonator 306 is optically decoupled from portion 310 of waveguide 308, resonator 306′ is then optically decoupled from portion 310′ of waveguide 308′.

For example, the relative position of the two resonators 306 and 306′ with respect to each other is fixed (constant), the relative position of portions 310 and 310′ with respect to each other is fixed (constant).

In the example of FIG. 13, resonator 306, and thus resonator 306′, are attached to the first one of the two elements movable with respect to each other, and portion 310 of waveguide 308, and thus portion 310′ of waveguide 308′, are attached to the second one of the two elements movable with respect to each other. Those skilled in the art will be capable of adapting the embodiment of FIG. 13 to the embodiment described in relation with FIGS. 9 and 10, by attaching portion 310 of waveguide 308, and thus portion 310′ of waveguide 308′, to the first one of the two elements movable with respect to each other, and, more particularly, to portion 304A, and by attaching resonator 306, and thus resonator 306′, to the second one of the two elements movable with respect to each other, for example to substrate 302 or to portion 304B, regardless of whether the latter is of the type described in relation with FIGS. 6 and 7, or of the type described in relation with FIG. 8.

In the example of FIG. 13, there are two sets of a resonator and of a waveguide portion, that is, a first set 306, 310 and a second set 306′, 310′. Those skilled in the art will be capable of generalizing this example to more than two sets of a resonator and of a waveguide portion.

The device 300 of the type described in relation with FIG. 13 enables to electrically enable and disable the optical coupling between a plurality of resonators and a plurality of respective waveguides.

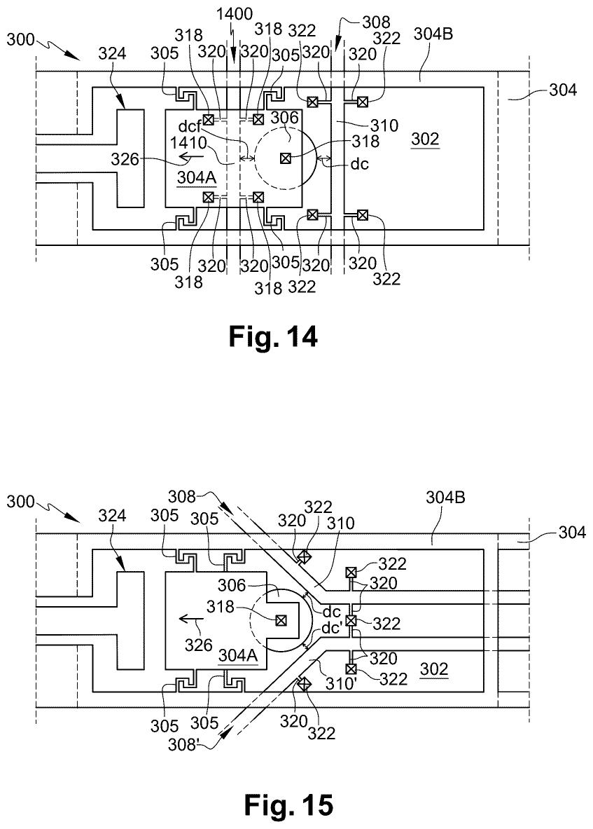

FIG. 14 shows, in a simplified top view, an example of still another embodiment of device 300, FIG. 14 being a simplified top view of device 300 similar to the top views of FIGS. 3, 6, 8, 10, 11, 12, and 13.

The device 300 of FIG. 14 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 14.

In this embodiment, device 300 comprises an additional waveguide 1400 having a portion 1410 attached to that of the first and second elements movable with respect to each other having resonator 306 attached thereto. Portion 1410 is attached so that the additional waveguide 1400, and more particularly its portion 1410, is optically coupled to resonator 306. For example, the relative position of portion 1410 with respect to resonator 306 is fixed (constant). In particular, the optical coupling gap dcf between portion 1410 and resonator 306 is fixed. As an example, waveguide 1400 is defined in the same layer 312 as resonator 306 and waveguide 308.

In this embodiment where resonator 306 is attached to the first one of the two elements movable with respect to each other, and more particularly to portion 304A of layer 304, portion 1410 of additional waveguide 1400 is also attached to this first element, and more particularly to portion 304A. For example, portion 1410 of additional waveguide 1400 is attached to portion 304A by holding arms 320 and by anchor pads 318, each holding arm 320 extending from portion 1400 to a corresponding pad 318.

In this embodiment, portion 310 of waveguide 308 is attached to the second one of the two elements movable with respect to each other. In this example, portion 310 of waveguide 308 is attached to substrate 302. However, in other examples, not shown, where the second element comprises portion 304B of layer 304, portion 310 may be attached to this portion 304B, as in FIGS. 6 and 7 and FIG. 8.

In the device 300 of FIG. 14, when the first and second elements movable with respect to each other are in the first position where resonator 306 is optically coupled to portion 310 of waveguide 308, since resonator 306 is optically coupled to portion 1410 of waveguide 1400, light can be transmitted from one to the other of waveguides 308 and 1400, via resonator 306. Conversely, when the first and second elements movable with respect to each other are in the second position where resonator 306 is optically decoupled from portion 310 of waveguide 308, although portion 1410 of the waveguide is optically coupled to resonator 306, light can no longer be transmitted from one to the other of waveguides 308 and 1400 via resonator 306.

In the example of FIG. 14, resonator 306 and portion 1410 of waveguide 1400 are attached to the first one of the two elements movable with respect to each other, and portion 310 of waveguide 308 is attached to the second one of the two elements movable with respect to each other. Those skilled in the art will be capable of adapting the embodiment of FIG. 14 to the alternative embodiment described in relation with FIGS. 9 and 10, by attaching portion 310 of waveguide 308 to the first one of the two elements movable with respect to each other, and, more particularly, to portion 304A, and by attaching resonator 306, and thus portion 1410 of waveguide 1400, to the second one of the two elements movable with respect to each other, for example to substrate 302 or to portion 304B, regardless of whether the latter is of the type described in relation with FIGS. 6 and 7, or of the type described in relation with FIG. 8.

FIG. 15 shows, in a simplified top view, still another embodiment of device 300, FIG. 15 being a simplified top view of device 300 similar to the top views of FIGS. 3, 6, 8, 9, 11, 12, 13, and 14.

The device 300 of FIG. 15 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 15.

In this embodiment, device 300 comprises an additional waveguide 308′ having a portion 310′ attached to that of the first and second elements movable with respect to each other having the portion 310 of waveguide 308 attached thereto.

In this embodiment where portion 310 of waveguide 308 is attached to the second one of the two elements movable with respect to each other, portion 310′ of additional waveguide 308′ is also attached to the second one of the two elements movable with respect to each other. For example, in this example where portion 310 of waveguide 308 is attached to substrate 302, portion 310′ of waveguide 308′ is also attached to substrate 302. However, in other examples, not shown, where the second element comprises, or corresponds to, portion 304B of layer 304, the portions 310 and 310′ of the respective waveguides 308 and 308′ may be attached to this portion 304B as is the case for portion 310 in FIGS. 6 and 7 and in FIG. 8.

In the device 300 of FIG. 15, when the first and second elements movable with respect to each other are in the first position where resonator 306 is optically coupled to portion 310 of waveguide 308, resonator 306 is then also optically coupled to portion 310′ of waveguide 308′, and light can be transmitted from one to the other of waveguides 308 and 308′, via resonator 306. Conversely, when the first and second elements movable with respect to each other are in the second position where resonator 306 is optically decoupled from portion 310 of waveguide 308, resonator 306 is then also optically decoupled from portion 310′ of waveguide 308′, and light can no longer be transmitted from one to the other of waveguides 308 and 308′ via resonator 306.

For example, the relative position of portions 310 and 310′ with respect to each other is fixed (constant).

In the example of FIG. 15, resonator 306 is attached to the first one of the two elements movable with respect to each other, and portion 310 of waveguide 308, and thus portion 310′ of waveguide 308′, are attached to the second one of the two elements movable with respect to each other. Those skilled in the art will be capable of adapting the embodiment of FIG. 15 to the alternative embodiment described in relation with FIGS. 9 and 10, by attaching portion 310 of waveguide 308, and thus portion 310′ of waveguide 308′, to the first one of the two elements movable with respect to each other, and, more particularly, to portion 304A, and by attaching resonator 306 to the second one of the two elements movable with respect to each other, for example to substrate 302 or to portion 304B, regardless of whether the latter is of the type described in relation with FIGS. 6 and 7, or of the type described in relation with FIG. 8.

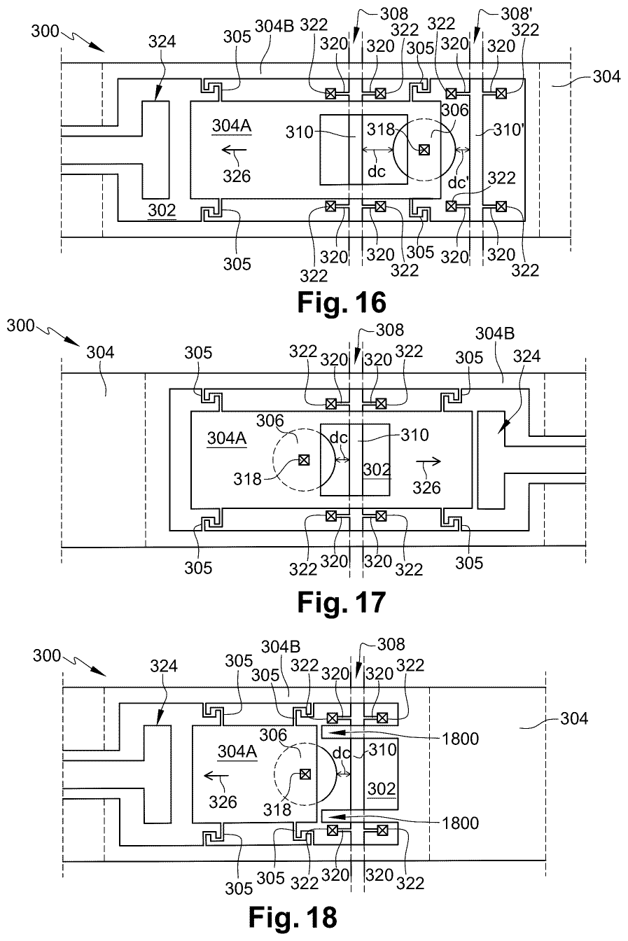

FIG. 16 shows, in a simplified top view, an example of still another embodiment of device 300, FIG. 16 being a simplified top view of device 300 similar to the top views of FIGS. 3, 6, 8, 9, 11, 12, 13, 14, and 15.

The device 300 of FIG. 16 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 16.

In this embodiment, device 300 comprises an additional waveguide 308′ comprising a portion 310′. As an example, waveguide 308′ is defined in the same layer 312 as resonator 306 and waveguide 308.

In this embodiment, where portion 310 of waveguide 308 is attached to the second one of the two elements movable with respect to each other, portion 310′ of additional waveguide 308′ is also attached to this second element.

In this example, portion 310 of waveguide 308 is attached to substrate 302, and portion 310′ of waveguide 308′ is then preferably attached to substrate 302, for example by anchor pads 322 and holding arms 320 each extending from portion 310′ to a corresponding pad 322. However, in other non-illustrated examples where the second element comprises portion 304B of layer 304, the portions 310 and 310′ of the respective waveguides 308 and 308′ may be attached to this portion 304B as is the case in FIGS. 6 and 7 and FIG. 8.

In the device 300 of FIG. 16, when the first and second elements movable with respect to each other are in the first position where resonator 306 is optically coupled to portion 310 of waveguide 308, resonator 306 is then optically decoupled from portion 310′ of waveguide 308′. Conversely, when the first and second elements movable with respect to each other are in the second position where resonator 306 is optically decoupled from portion 310 of waveguide 308, resonator 306 is then optically coupled to portion 310′ of waveguide 308′.

For example, the relative position of the two portions 310 and 310′ with respect to each other is fixed (constant). For example, these portions 310 and 310′ are respectively arranged on either side of resonator 306, for example, in the direction of relative displacement of the first and second elements with respect to each other.

In the example of FIG. 16, resonator 306 is attached to the first one of the two elements movable with respect to each other, and portion 310 of waveguide 308, and thus portion 310′ of waveguide 308′, are attached to the second one of the two elements movable with respect to each other. Those skilled in the art will be capable of adapting the embodiment of FIG. 16 to the alternative embodiment described in relation with FIGS. 9 and 10 where the portions 310 and 310′ of the respective waveguides 308 and 308′ are attached to the first one of the two elements movable with respect to each other, and, more particularly, to portion 304A, and where resonator 306 is attached to the second one of the two elements movable with respect to each other, for example by attaching resonator 306 to substrate 302 or to portion 304B, whether it is of the type described in relation with FIGS. 6 and 7, or of the type described in relation with FIG. 8.

The device 300 of the type described in relation with FIG. 16 enables to control which of waveguides 308 and 308′ resonator 306 is coupled to.

FIG. 17 shows, in a simplified top view, an example of an alternative embodiment of device 300, FIG. 17 being a simplified top view of device 300 similar to the top views of FIGS. 3, 6, 8, 9, 11, 12, 13, 14, 15, and 16.

The device 300 of FIG. 17 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 17.

In the examples of embodiments and variants previously described in relation with FIGS. 3 to 16, actuator 324 comprises, as an example, an electrostatic actuator, and, as a more specific example, an electrostatic actuator in which resonator 306 and portion 310 of waveguide 308 are in their first relative position with respect to each other when no biasing is applied between the electrodes of this actuator, and resonator 306 and portion 310 of waveguide 308 are in their second relative position with respect to each other when a non-zero, for example positive, biasing is applied between the electrodes of this actuator.

In the embodiment of FIG. 17, the electrostatic capacitive actuator has a symmetrical operation. In this variant, resonator 306 and portion 310 of waveguide 308 are in their first relative position with respect to each other when a non-zero, for example positive, biasing is applied between the electrodes of actuator 324, and resonator 306 and portion 310 of waveguide 308 are in their second relative position with respect to each other when no biasing is applied between the electrodes of actuator 324. For example, the position of the actuator with respect to portion 304A in the direction of displacement of portion 304A is reversed.

Those skilled in the art will be capable of adapting this variant to the example of embodiments and variants previously described in relation with FIGS. 3 to 16.

Further, although examples of embodiments and of variants have been described in which actuator 324 comprises a single capacitive electrostatic actuator, the actuator may, in other examples, comprise a plurality of, for example two, capacitive electrostatic actuators, for example arranged on either side of portion 304A. For example, this may allow a better control of the value of coupling gap dc.

FIG. 18 shows, in a simplified top view, an example of an alternative embodiment of device 300, FIG. 18 being a simplified top view of device 300 similar to the top views of FIGS. 3, 6, 8, 9, 11, 12, 13, 14, 15, 16, and 17.

The device 300 of FIG. 18 has many similarities and features in common with the device 300 in FIGS. 3 to 5, and only the differences between these two devices 300 are here highlighted. Thus, unless otherwise indicated, all that has been described for the device 300 of FIGS. 3 to 5 applies to the device 300 of FIG. 18.

The device 300 of FIG. 18 differs from the device 300 of FIGS. 3 to 5 in that it comprises at least one stop 1800, for example two stops 1800 in the example of FIG. 18.

Stop(s) 1800 is or are configured to limit the displacement of portion 304A, so as to limit the displacement of resonator 306 with respect to the portion 310 of waveguide 308. More particularly, the stop(s) are configured to prevent for resonator 306 and portion 310 to come into contact with each other. In other words, stop(s) 1800 determine a non-zero minimum gap between resonator 306 and portion 310 of waveguide 308. Still in other words, stop(s) 1800 determine the minimum value of the coupling gap between resonator 306 and portion 310 of waveguide 308.

As an example, this non-zero minimum gap between resonator 306 and portion 310 of waveguide 308 is that which is present between resonator 306 and portion 310 of waveguide 308 when portion 304A comes into contact with stops 1800. Stops 1800 then each comprise a portion of layer 304.

As an alternative example, this non-zero minimum gap between resonator 306 and portion 310 of waveguide 308 is that which is present between resonator 306 and portion 310 of waveguide 308 when a portion of layer 312 attached to portion 304A comes into contact with stops 1800. Stops 1800 then each comprise a portion of layer 312. Layer 312 being preferably thinner than layer 304, this may allow a greater accuracy on the dimensions of the stops as compared with the previous example.

As an example, the relative position of stop(s) 1800 with respect to the second one of the two elements movable with respect to each other is fixed (constant). In the example of FIG. 18, where the second element corresponds to substrate 302, the stop(s) are, for example, fixed with respect to substrate 302.

Those skilled in the art will be capable of providing such stops 1800 in the previously-described examples of embodiments and of variants.

Further, those skilled in the art will be capable of providing stops similar to stops 1800, but which are configured to determine a minimum gap between resonator 306 and portion 310′ of guide 308′ (for example in FIGS. 15 and 16), or between resonator 306′ and portion 310 (for example in FIG. 11).

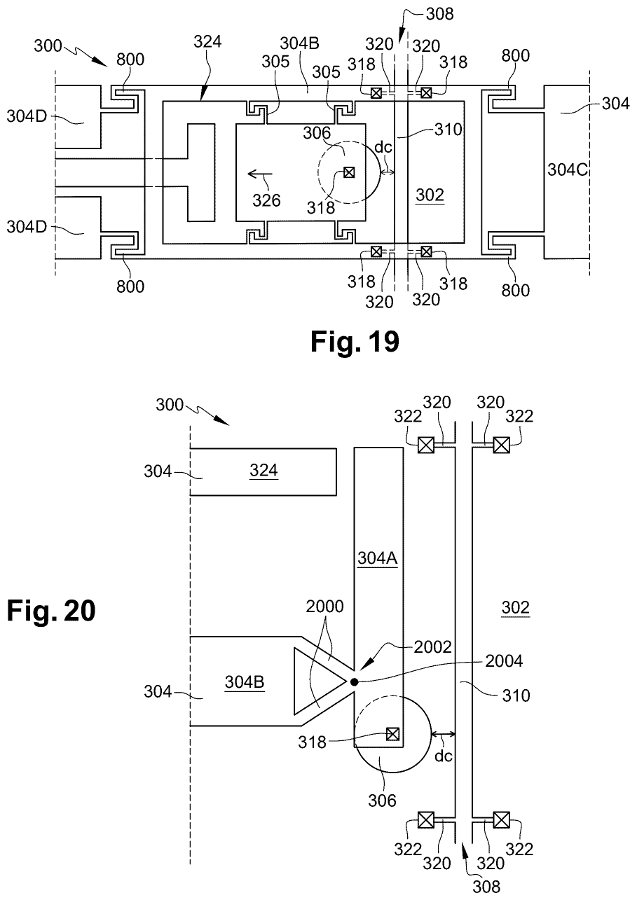

FIG. 19 shows, in a simplified top view, an example of an alternative embodiment of device 300, FIG. 19 being a simplified top view of device 300 similar to the top views of FIGS. 3, 6, 8, 9, 11, 12, 13, 14, 15, 16, 17, and 18.

The device 300 of FIG. 19 has many similarities and elements in common with the device 300 of FIG. 8, and only the differences between these two devices 300 are here highlighted. Thus, unless otherwise indicated, all that has been described for the device 300 of FIG. 8 applies to the device 300 of FIG. 19.

In the device 300 of FIG. 8, portion 304B is considered as fixed with respect to substrate 302, although one or more flexible links 800 couple a part of portion 304B suspended above substrate 302 to a fixed portion 304C of layer 304. This is due to the fact that another part of portion 304A keeps a direct mechanical connection with a portion 304D of layer 304 which is fixed with respect to substrate 302.

In the device 300 of FIG. 19, portion 304B of layer 304 is entirely suspended above substrate 302, and is no longer connected to portion 304D of layer 304, which is fixed with respect to the substrate. Indeed, in FIG. 19, portion 304B is coupled to each of portions 304C and 304D by links 800. As a result, portion 304B is movable with respect to the substrate. Links 800 enable to absorb stress (deformations and/or vibrations) that substrate 302 might transmit to portion 304B.

In other words, in the device 300 of FIG. 19, portions 304A and 304B are mechanically coupled to each other by at least one link 305 allowing a displacement of portion 304A with respect to portion 304B, and portion 304B is coupled to substrate 302 by at least one link 800 allowing a displacement of portion 304B with respect to substrate 302. For example, portion 304B is coupled to substrate 302 by at least one link 800 between layer portion 304A and a portion 304C, 304D of layer 304 which is fixed with respect to the substrate.

In the device 300 of FIG. 19, the second one of the two elements movable with respect to each other comprises, for example, portion 304B of layer 304.

Those skilled in the art will be capable of adapting this variant to the example of embodiments and variants described hereabove in relation with FIGS. 9 to 16.

FIG. 20 shows, in a simplified top view, an example of another embodiment of optoelectronic device 300, FIG. 20 being a simplified top view of device 300 similar to the top views of FIGS. 3, 6, 8, 9, 11, 12, 13, 14, 15, 16, 17, 18, and 19.

The device 300 of FIG. 20 has many similarities and features in common with the device 300 of FIGS. 3 to 5, and only the differences between these two devices 300 are here highlighted. Thus, unless otherwise indicated, all that has been described for the device 300 of FIGS. 3 to 5 applies to the device 300 of FIG. 20.

In the examples of embodiment and of variants described hereabove in relation with FIGS. 3 to 19, portion 304A is movable with respect to substrate 302 by means of links 305, or even links 305 and 800. Links 305 and 800 are flexible links.

However, in other embodiments, links other than flexible links may be provided, so that the first one of the two elements movable with respect to each other, which comprises portion 304A movable with respect to substrate 302, is movable with respect to the first one of the two elements movable with respect to each other.

For example, a pivot link may be provided between these first and second elements, as is the case in the embodiment illustrated in FIG. 20.

More particularly, in the example of FIG. 20, portion 304B of layer 304 is fixed with respect to substrate 302. For example, although this is not shown in FIG. 20, portion 304B of layer 304 rests on top of and in contact with the stack of layers 316, 312, 314, this stack resting on top of and in contact with substrate 302.

Portion 304A of layer 304 is suspended above substrate 302 and is mechanically coupled to portion 304B by a pivot link 2002, for example a single pivot link 2002. Pivot link 2002 comprises, for example, two holding arms 2000 at least partly formed in layer 304. Each arm 2000 extends from portion 304B to a same region of portion 304A where arms 2002 meet. This region corresponds to the pivot point 2004 of pivot link 2002.

Portion 304A forms a lever arm for the pivot link. In the example of FIG. 20, arm 304A may pivot around pivot point 2004, in a plane parallel to surface 303 (not referenced in FIG. 20) of substrate 302.

In this embodiment, the first one of the two elements movable with respect to each other comprises portion 304A, for example corresponds to this portion 304A. The second one of the two elements movable with respect to each other comprises substrate 302, for example corresponds to substrate 302.

In the example of FIG. 20, resonator 306 is attached to portion 304A, for example by an anchor pad 318. For example, resonator 306 is attached to portion 304A at one end of the lever arm formed by portion 304A relative to pivot point 2004. In the example of FIG. 20, portion 310 of waveguide 308 is attached to substrate 302, for example by holding arms 320 and anchor pads.

As an alternative example, resonator 306 may be attached to substrate 302 and portion 310 may be attached to portion 304A. However, the implementation of this other example may prove more complex than that of the example illustrated in FIG. 20, and, further, may lead to deformations of waveguide 308 beyond portion 310.

Actuator 324 is here configured to controllably pivot portion 304A around pivot point 2004. For example, actuator 324 is arranged close to the end of lever arm 304A opposite to the end of arm 304A where the resonator is attached. As an example, arm 304A extends lengthwise in a direction parallel to that in which the portion 310 of waveguide 308 extends lengthwise.

For example, actuator 324 is an electrostatic actuator, for example a capacitive electrostatic actuator.

The provision of a pivot link to control the relative displacement of portion 304A, and thus of resonator 306 in the shown example, with respect to substrate 302, and thus to the portion 310 of waveguide 308 in the shown example, enables, depending on the arrangement of pivot point 2004 along the length of arm 304A:
either to decrease the amplitude of the displacement between resonator 306 and portion 310 of waveguide 308 relative to the amplitude of the displacement between arm 304A and actuator 324;
or, conversely, to amplify the amplitude of the displacement between resonator 306 and portion 310 of waveguide 308 relative to the amplitude of the displacement between arm 304A and actuator 324.

Although this is not shown in FIG. 20, those skilled in the art will be capable of providing one or more stops 1800 in the device 300 of FIG. 20, for example on actuator 324. For example, such a stop 1800 is configured so that, when the end of arm 304A moves towards actuator 324 when actuator 324 controls a movement of resonator 306 and of portion 310 towards each other, this end of arm 304A comes into contact with the stop when resonator 306 and portion 310 are in the first position where they are optically coupled.

Those skilled in the art will be capable of adapting the embodiments described in relation with FIGS. 11 to 18 to the embodiment of FIG. 20.

As an example, in the embodiments and variants previously described in relation with FIGS. 3 to 20, layer 312 is a semiconductor layer of a silicon-on-insulator (SOI) structure, layer(s) 314 corresponding to the insulating layer of this SOI structure, and substrate 302 corresponding to the substrate having the SOI structure resting thereon. As an example, layer(s) 316 are dielectric layers formed on layer 312 before a semiconductor substrate is deposited on layer(s) 316 and then thinned. As an alternative example, layer(s) 316 are formed on a semiconductor substrate, after which the assembly of semiconductor substrate and of layers 316 is transferred onto layer 312 before this substrate is thinned.

As an example, layer 304 has a thickness in the range from 200 nm to 100 μm. As an example, layer 312 has a thickness in the range from 200 nm to 500 nm.

As an example, the minimum distance between two portions of layer 304, in the absence of an action of actuator 324 to bring these two portions closer together, is for example in the range from 500 nm to 1 μm, and depends, for example, on the etching processes used to define these two portions in layer 304.

As an example, the minimum distance between two portions of layer 312, in the absence of an action of actuator 324 to bring these two portions closer together, is for example in the order of 100 nm, and depends, for example, on the etching processes used to define these two portions in layer 304.

As an example, the amplitudes of displacement of portion 304A with respect to the part of the actuator 324 which is fixed with respect to substrate 302 are in the range from approximately 50 nm to 1 μm.

As an example, in the embodiment of FIG. 20, arm or portion 304A has a length in the range from 10 to 1,000 μm, and the position of pivot point 2004 along arm 304A is configured to obtain a decrease by a factor in the range from 1 to 100 of the amplitude of the displacement between resonator 306 and portion 310 of waveguide 308 with respect to the amplitude of the displacement between arm 304A and actuator 324, or an increase by a factor in the range from 1 to 100 in the amplitude of the displacement between resonator 306 and portion 310 of waveguide 308 with respect to the amplitude of the displacement between arm 304A and actuator 324.

In the example of embodiments and variants described in relation with FIGS. 3 to 20, actuator 324 is configured to control the relative position of resonator 306 and of portion 310 of the waveguide between:
a first position where these two elements are optically coupled, for example when the optical coupling rate is at its maximum value for the considered device 300, and
a second position where these two elements are optically decoupled from each other, for example when the coupling rate is at its minimum value for the considered device 300. In other examples, actuator 324 may be configured to control at least one other relative position of resonator 306 with respect to portion 310 of waveguide 308, for example to continuously control this relative position between the first and second relative positions described hereabove. This enables, for a given device 300, the coupling rate between resonator 306 and the portion 310 of waveguide 308 to take at least one other value between the above-described minimum and maximum values. For example, it can be envisaged to generate a continuous modulation of the coupling rate according to a periodic signal having a frequency fmod in the range from 0 Hz to fc, fc being a mechanical cut-off frequency which depends on the mass of the system and on the mechanical stiffnesses involved, so as, for example, to modulate the optical signal in resonator 306 with a displacement of the movable elements which could be, for example, smaller than or greater than Le. As an example of application, such a continuous modulation may enable to encode information in the optical signal.

More generally, when it is indicated that actuator 324 is configured to modify the relative position of resonator 306 and of portion 310 of the waveguide between a first position where these two elements are optically coupled, and a second position where these two elements are optically decoupled from each other, this means, for example, that actuator 324 is configured to control at least two different positions of the first and second elements with respect to each other, one of these at least two positions corresponding to the first position or to a position intermediate between the first and second positions, and another of these at least two positions corresponding to the second position or to another position intermediate between the first and second positions. In other words, when it is indicated that actuator 324 is configured to modify the relative position of resonator 306 and of portion 310 of the waveguide between a first position where these two elements are optically coupled, and a second position where these two elements are optically decoupled from each other, this means, for example, that actuator 324 is configured to control at least two different positions of the first and second elements relative to each other, each of these at least two positions corresponding to a different optical coupling, or optical coupling rate, between resonator 306 and waveguide 308. Preferably, actuator 324 is configured so that the first and second elements are in the first position with respect to each other for a first state of the actuator, and are in the second position with respect to each other for a second state of the actuator.

In the example of embodiments and of variants described in relation with FIGS. 3 to 19, portion 304B has a generally rectangular shape. However, the described embodiments and variants are not limited to a portion 304B having the general shape of a frame, and those skilled in the art will be capable of providing other shapes of portions 304A.

In the example of embodiments and variants described in relation with FIGS. 3 to 20, the first and second elements movable with respect to each other displace with respect to each other in a direction parallel to the surface 303 of substrate 302. Those skilled in the art will be capable of implementing a device 300 in which the first and second elements movable with respect to each other displace with respect to each other in a direction orthogonal to the surface 303 of substrate 302, and will know how to adapt the described embodiments and variants to such a device 300.

In the described example of embodiments and variants, actuator 324 is a capacitive electrostatic actuator. Those skilled in the art will be capable of providing one or more actuators 324 of other types, for example of piezoelectric or electrothermal type.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Optomechanical device comprising:
a first element and a second element mechanically movable with respect to each other;
a waveguide comprising a portion attached to one of the first and second elements;
an optomechanical resonator attached to the other of the first and second elements; and
an actuator configured to modify a relative position of the first and second elements with respect to each other between a first position where the resonator is optically coupled to said portion of the waveguide and a second position where the resonator is optically decoupled from said portion of the waveguide.

2. Device according to claim 1, wherein:
the device comprises a substrate and a first layer resting on the substrate;
the first layer comprises a first portion suspended above the substrate and movable with respect to the substrate; and
the first element of the device comprises the first portion of the first layer.

3. Device according to claim 2, wherein the first layer extends in thickness in a direction orthogonal to a main surface of the substrate and the first portion of the first layer is movable with respect to the substrate in a plane parallel to the main surface of the substrate.

4. Device according to claim 2, wherein:
the first layer comprises a second portion which is fixed with respect to the substrate;
the first and second portions of the first layer are mechanically coupled to each other by at least one link allowing a relative movement of the first and second portions of the first layer with respect to each other; and
the second element of the device comprises the substrate or the second portion of the first layer.

5. Device according to claim 4, wherein said at least one link comprises a single pivot link and the second element of the device comprises the substrate.

6. Device according to claim 2, wherein:
the first layer comprises a second portion suspended above the substrate and movable with respect to the substrate;
the first and second portions of the first layer are mechanically coupled to each other by at least one link allowing a relative movement of the first and second portions with respect to each other;
the second portion of the first layer and the substrate are mechanically coupled to each other by at least one link allowing relative movement of the second portion of the first layer and of the substrate with respect to each other; and
the second element of the device comprises the second portion of the first layer.

7. Device according to claim 2, wherein the device comprises a second layer resting on the substrate, between the substrate and the first layer, the resonator and the waveguide being defined in the second layer.

8. Device according to claim 7, wherein the device comprises at least a third layer between the substrate and the second layer and at least a fourth layer between the second layer and the first layer.

9. Device according to claim 8, wherein the portion of the waveguide or the resonator which is attached to the first portion is attached to this first portion by at least one anchor pad defined in said at least one fourth layer.

10. Device according to claim 4, wherein said at least one link is at least partly defined in the first layer.

11. Device according to claim 2, wherein the actuator comprises at least one electrostatic actuator comprising a capacitive element having a first electrode at least partly defined in the first element.

12. Device according to claim 1, wherein the device comprises at least one stop determining a non-zero minimum gap between the portion of the waveguide and the resonator in the first position.

13. Device according to claim 1, wherein the device comprises an additional optical or optomechanical resonator attached to said other of the first and second elements so that:
the additional resonator is optically decoupled from said portion of the waveguide in the first position and is optically coupled to said portion of the waveguide in the second position; or
the additional resonator is optically coupled to said portion of the waveguide in the first position and is optically decoupled from said portion of the waveguide in the second position; or
the additional resonator is optically coupled to a portion of an additional waveguide of the device in the first position and is optically decoupled from said portion of the additional waveguide in the second position, said portion of the additional waveguide being attached to one of the first and second elements.

14. Device according to claim 1, wherein the device comprises an additional waveguide having a portion attached to said one of the first and second elements so that:
the resonator is optically decoupled from said portion of the additional waveguide in the first position and is optically coupled to said portion of the additional waveguide in the second position; or
the resonator is optically coupled to said portion of the additional waveguide in the first position and is optically decoupled from said portion of the additional waveguide in the second position.

15. Device according to claim 1, wherein the device comprises an additional waveguide having a portion attached to said other one of the first and second elements so that said portion of the additional waveguide is optically coupled to the resonator.
